(19) United States
(12) Patent Application Publication
(10) Pub. No.: US 2017/0233887 A1
(43) Pub. Date: Aug. 17, 2017

(54) Methods of Producing a Semiconductor with Decreased Oxygen Contamination and Impurities

(71) Applicant: Mossey Creek Technologies, Inc., Jefferson City, TN (US)

(72) Inventors: John Carberry, Talbott, TN (US); Tim Wilson, Lafayette, TN (US)

(21) Appl. No.: 15/367,397

(22) Filed: Dec. 2, 2016

Related U.S. Application Data
(60) Provisional application No. 62/262,020, filed on Dec. 2, 2015.

(51) Int. Cl. C30B 11/06; C30B 11/00; C30B 29/06; C30B 11/02

(52) U.S. Cl. CPC C30B 11/065; C30B 11/02; C30B 11/002; C30B 29/06; H01L 31/1804

(57) ABSTRACT

A method for manufacturing a semiconductor for a solar cell and other applications is disclosed. A separating layer may be introduced into a mold having an interior defining a shape of a solar cell or other substantially planer object. A silicon nitride coating may be applied onto one or more interior surfaces of the mold. A planar capillary space is formed along the conductive layer. The silicon is melted under an ultra-low oxygen content cover atmosphere and allowed to flow into the capillary space. The melted silicon is then cooled within the capillary space such that the silicon forms one part of a P-N junction in the body of the semiconductor.

### REFERENCE TO RELATED APPLICATIONS

This application claims the benefit of U.S. Provisional Application No. 62/262,020 entitled “Method of Producing a Semiconductor with Decreased Oxygen Contamination and/or A Low Temperature formed Mold Interior Surface” filed Dec. 2, 2015, which is incorporated by reference in its entirety.

### BACKGROUND

1. Field of Invention

The present general inventive concept pertains to the making of a silicon wafer useful as a semiconductor and for photovoltaic cell production. The wafer has decreased oxygen contamination in relation to conventional wafers and may be beneficially formed from a mold having an interior surface coating formed at low temperature. Other applications for such net shape planer shapes, or net shape planer shapes with particular surface geometries on one of both sides are also addressed.

2. Description of the Related Art

Photovoltaic cells, commonly known as solar cells, are known devices used for direct conversion of solar radiation into electrical energy. Generally, solar cells are fabricated on a semiconductor wafer or substrate using semiconductor processing techniques to form a p-n junction near a surface of the semiconductor substrate. Solar radiation contacting the surface of the semiconductor substrate creates electron and hole pairs in the bulk of the substrate, which migrate to p-doped and n-doped regions in the substrate, thereby generating a voltage differential between the differently doped regions of the semiconductor substrate. The doped regions of the semiconductor substrate are coupled to a conductor on the solar cell to direct electrical current from the cell to an external circuit. Commonly, the n-type junction, such as provided by phosphorous doping, is on the surface of the semiconductor substrate, while the p-type junction, such as provided by boron doping, is within the body of the semiconductor substrate.

Use of solar cells in electrical energy production is attractive, in part due to the inexpensive nature of solar radiation used to fuel energy production in the solar cells. As concerns rise as to the environmental cost of carbon dioxide emissions with respect to global warming and the acidification of the seas, and as the fuel costs associated with more conventional means of electrical energy production can be expected to increase, demand for solar cells for electrical energy production also increases.

Previous methods for production of solar cells have proven to be labor intensive, energy intensive, and materials intensive, and such previous methods have often resulted in the production of solar cells having relatively low efficiency and high cost in electrical energy production. For example, in one known method of producing solar cells, a polycrystalline silicon material is used as the substrate. In this method, polycrystalline silicon wafers are obtained by first placing and packing essentially pure lumps of silicon in a crucible. The crucible is loaded into a vacuum furnace that has heating elements made of graphite. The vacuum furnace heats the silicon lumps, causing the lumps to melt. The melted silicon is then allowed to cool to encourage the formation of a large silicon ingot including polycrystalline crystal formations.

The crucible is commonly constructed of fused silica and, because of the processing temperature of the vacuum furnace, the fused silica forming the walls of the crucible partially converts to crystobalite during the melting of the lumps of silicon. Thus, the crucible is generally limited to a single use due to the degradation of its interior surface.

This melting process produces a polycrystalline silicon ingot having a large outer volume contaminated by impurities. Thus, to fabricate a useful wafer, the large outer volume of silicon contaminated by impurities is cut away and discarded following manufacture of the ingot. Thereafter, the remaining purer inner portion of the ingot is thin-cut into discreet wafers using a wire saw. The wire saw causes additional material loss at it removes material between successively cut wafers and also limits the minimum thickness of the cut wafer to a thickness that can withstand the mechanical stress of the sawing process without breaking. The saw-cut polycrystalline silicon wafers are then laminated to a conductive layer to form a solar cell.

The time required to complete the heating and cooling cycles of the crucible including the silicon is often in the 45 to 60 hour range. Thus, the time associated with forming the polycrystalline silicon ingot can result in significant delays in the production process.

One factor in determining the length of the heating and cooling cycles is the time required to heat the silicon in the crucible sufficiently to cause the silicon to melt. As a general rule, the smaller the initial lumps of silicon to be melted, the shorter the heating cycle required for sufficient melting of the silicon. However, the process of reducing larger silicon lumps into smaller silicon granules often coats undesirable contaminants onto the surface of the smaller silicon granules. Thus, while melting smaller silicon granules provides a shorter heat time to melt the silicon, undesirable contamination of the resulting silicon ingot results. Due to this contamination issue arising from the formation of smaller silicon granules, larger silicon lumps having an average size of approximately thirty (30) millimeters are conventionally used. Use of such coarse materials helps to preserve purity in the melted silicon. However, the packing density of these larger silicon lumps in the crucible is approximately 35% of perfect packing, which is significantly less than ideal, with much of the interior volume of the crucible being open space.

Due to the open space in the crucible during heating, heat is not conducted efficiently through the larger silicon lumps, and additional heating time is required. Given that (1) the heating elements are on the outside of the crucible, (2) the larger silicon lumps have relatively little physical contact with one another, and (3) the larger silicon lumps often serve to “shadow” one another from thermal radiation; most of the heating occurs by thermal radiation that is accomplished in succession. Heating in succession means that when a relatively exposed silicon lump is heated, that lump then radiates heat to one or more successive relatively unexposed or shadowed lumps. A partial pressure of argon gas is often used during heating to assist in transferring heat between the larger silicon lumps.

This process of melting silicon often results in undesirable impurities being formed in the silicon ingot, which contribute to a relatively low yield of polycrystalline silicon and a low sunlight to electrical energy conversion efficiency in the resulting polycrystalline silicon wafer. During such conventional heating and subsequent cooling of the silicon, impurities including iron, silicon carbide (SiC), and dissolved oxygen complexes (including silicon-oxygen and carbon-oxygen complexes) form in the silicon feedstock. The impurities may cause a reduction in the yield of usable silicon crystal wafers that can be as high as approximately 40%. The impurities also may cause defects in the crystal structure that reduce the sunlight conversion efficiency and useful service life of the resulting solar cell.

Multiple factors encourage the synthesis of these impurities. First, the high temperature achieved in the furnace promotes the oxidation of the graphite heating elements of the furnace through a reduction of the fused silica contacting the graphite. This reaction creates carbon oxide gases including carbon monoxide (CO) and carbon dioxide (CO₂) from the graphite of the heating elements. Other components of the vacuum furnace composed of graphite also may be oxidized during heating of the crucible to form carbon oxide gases. First, the formed carbon oxide gases react with the silicon in the mold to yield silicon carbide and silicon oxides. Second, although the rebonded fused silica forming the crucible is a highly refractory substance, it is permeable to carbon oxide gases. Thus, carbon oxide gases may access the silicon by permeating the crucible during heating. Third, the packing density of the larger silicon lumps results in open spaces between the larger silicon lumps that can be permeated and occupied by the carbon oxide gases. The surfaces of the larger silicon lumps that border these open spaces serve as additional loci for the formation of silicon carbide and silicon oxides.

Furthermore, as the fused silica forming the walls of the crucible converts to cristobalite during heating, the pure precipitating cristobalite crystals isolate the other impurities in the fused silica into grain boundaries, where they lower the viscosity of the evolving glass. Since dissolved iron is a typical impurity in the fused silica, often in the range of 300 ppm, this diffuses into the liquidus silicon where diffusion rates can travel at cm per second. This iron is further zone refined into and near the grain boundaries of the silicon crystals by the same dynamics during heating.

Because of the process time of the vacuum furnace and the size of the melted silicon ingot, it is impractical to directly “dope” the melted silicon ingot to form the body of the n-type or p-type junction. Because of the limits of the doping technology, doping of the silicon is generally limited to using boron in the body of the silicon wafer to make the p-type junction and using phosphorous at the surface of the silicon wafer to make the n-type junction. However, the methods of applying phosphorous or arsenic or other typical semiconductor dopants to the surface of the silicon result in much larger coatings than are needed or can be achieved within the silicon using boron. Finally, it must be acknowledged that vacuum furnaces generally do not create perfect vacuums, allowing atmospheric gases and potentially other gases to enter. Atmospheric gases include oxidizing agents that can result in the production of impurities in the formed silicon ingot. The oxygen content of the atmosphere at standard temperature and pressure (STP) is one mole for approximately 65 liters of atmosphere, meaning that 20.9% of 6.023×10^{23rd} oxygen atoms are present in the atmosphere at STP. Displacement by inert gases can result in a reduction of two or three orders of magnitude, such displacement being limited by turbulence defined by differential mass transport profiles.

A further yield loss is incurred by the sawing and slicing of the billet into wafers and subsequent tooling to attach the conductor, thereby forming the solar cell. Polycrystalline silicon is a relatively hard and brittle material, and thus, the operations of cutting the polycrystalline material and attaching the conductor are inherently difficult and labor intensive and result in a high mortality rate of the thin-cut silicon wafers due to fracture of the wafers during tooling and handling. In at least some instances, by the time the above-discussed contaminated outer layer is removed from the silicon ingot and the ingot is sliced down to silicon wafers having a thickness of approximately 150-200 microns, by the time the conductors are attached to the silicon wafers, and by the time resultant fractured wafers are discarded, the yield of usable thin-cut silicon wafers on starting silicon can be as low as 35%. The resultant wafers have an input silicon raw materials weight of about 24 grams to have the desired energy output. In addition, wire sawing causes well known, microcracks, typically about 15-25 microns deep on either side which have been shown to decrease carrier life time, efficiency and causing post infancy mortality in downstream processes right through to module operation in the field. As a result most wire cut wafers are etched with hydrofluoric acid to remove a thickness on either side to remove that layer diminished in reliable mechanical and functional quality, a costly and in fact hazardous process. In light of the above, the low yield of usable silicon wafer material and the high costs per unit of solar conversion efficiency associated with manufacture of solar cells using the above-discussed process have made use of solar cells manufactured by the above-discussed process for electrical energy production in the residential, commercial, and utility sectors impractical in many applications from an economical point of view without large subsidies from governments and the like.

If a silicon wafer body is uniformly doped at low levels with phosphorous or arsenic or other well-known semiconductor dopants, use of boron or other P type dopant to dope the surface of the silicon wafer to establish a p-type junction results in greatly increased efficiency in converting photons to electrons by the resultant solar cell. However, prior art doping technology makes this type of uniform doping of phosphorous in a solar grade silicon wafer impractical in a commercial setting. Furthermore, while a silicon wafer of approximately 180 microns in thickness captures substantially all sunlight, a silicon wafer of approximately 40 microns still captures most sunlight, i.e., in excess of 96% of sunlight in normal conditions. However, such a 40 micron wafer cannot be made and handled by conventional technology absent significant breakage of the wafer as previously discussed.

### BRIEF SUMMARY OF THE INVENTION

The present general inventive concept provides a method of producing a solar cell which allows for the production of a solar cell with reduced waste of silicon feedstock as compared with certain prior art methods. One embodiment of the present general inventive concept can be achieved by introducing a separating layer or material into or as a mold having an interior defining a shape of a solar cell, which will not react or “wet” with silicon, forming a planar capillary space along the separating layer or material, placing a measure of silicon in fluid communication with the capillary space, melting the silicon in an ultra-low oxygen content cover atmosphere, allowing the melted silicon to flow into and be trapped in the capillary space, and cooling the melted silicon within the capillary space. In one embodiment, the operation of melting the silicon is limited to heating the silicon to a temperature to 1450 degrees Centigrade or less, preferably to a temperature from 1420 C to 1430 C, and more preferably to a temperature from 1414 C to 1420 C. Preferably, the silicon is not heated above 1430 C. Thus, heating is limited to a temperature in excess of silicon's melting point (1414 C), but less than 1500 degrees C.

One embodiment of the present general inventive concept provides that the provided silicon ingot produced from the heating process is greater than 99.999% pure. Another embodiment provides that the produced silicon ingot is greater than 99.9999999% pure.

Example embodiments of the present general inventive concept can be achieved by placing a measure of dopant in the mold between the conductive layer and the capillary space, where the dopant can react with the silicon powder to produce a compound beneficial in forming the p-n junction of the solar cell. In certain embodiments, the dopants are selected from the group consisting of boron and phosphorous. Unlike a crucible, a mold includes interior dimensions that define the finished wafer without a wire saw, as will be discussed further below.

Example embodiments of the present general inventive concept can be achieved by using a mold, which is at least translucent to radiant light energy. For example, in one embodiment, the mold is fabricated from graphite and coated with a non-wetting, non-reacting ceramic. In another embodiment, the mold is constructed of silicon nitride ceramics. Example embodiments of the present general inventive concept can also be achieved by using a mold fabricated from a material capable of being quickly heated by inductive heating. For example, in certain embodiments, the mold is fabricated from quartz coated with a non-wetting, non-reacting coating, or graphite. In more discreet embodiments, one or more interior surfaces of a quartz mold are sprayed with a coating composition slurry that is substantially non-reactive to silicon powder. In certain embodiments, the operation of melting the silicon within the mold includes heating the mold with an inductive heating coil to transfer heat from the mold to the silicon, thereby melting the silicon.

In one embodiment, the non-reactive material coating the mold is silicon nitride.

### BRIEF DESCRIPTION OF THE SEVERAL VIEWS OF THE DRAWINGS

The above-mentioned and other features of the invention will become more clearly understood from the following detailed description of the invention read together with the drawings in which:

FIG. 1 is a flowchart showing one embodiment of the method of producing a solar cell of the present invention;

FIG. 2 is a flowchart showing one method of providing a slurry useful in the method of producing a solar cell;

FIG. 3 is a flowchart showing one method of providing a mold useful in the method of producing a solar cell;

FIG. 4 is a cross-sectional view showing a mold containing various components useful in the method of producing a solar cell;

FIG. 5 is a cross-sectional view of the mold and components of FIG. 4, showing application of radiant light energy to the mold to heat the components;

FIG. 6 is a cross-sectional view of the mold of FIG. 5, showing the finished solar cell following heating and cooling of the mold components;

FIG. 7 is a cross-sectional view of a mold containing various components useful in the method of producing a solar cell;

FIG. 8 is a flowchart showing another embodiment of the method of producing a solar cell;

FIG. 9 is a flowchart showing a method of forming a silicon nitride coating to on one or more interior surface of the mold useful in the method of producing a solar cell;

FIG. 10 is a schematic side view depicting conveyance of the mold of FIG. 7 through an induction heating apparatus;

FIG. 11 is a cross-sectional view of the mold of FIG. 7, showing the finished solar cell following heating and cooling of the mold components;

FIG. 12 is a cross-sectional view of a mold containing various components useful in performing another embodiment of the method of producing a semiconductor; and

FIG. 13 is a cross-sectional view of the mold of FIG. 12 containing the finished semiconductor following heating and cooling of the mold components.

### DESCRIPTION OF THE INVENTION

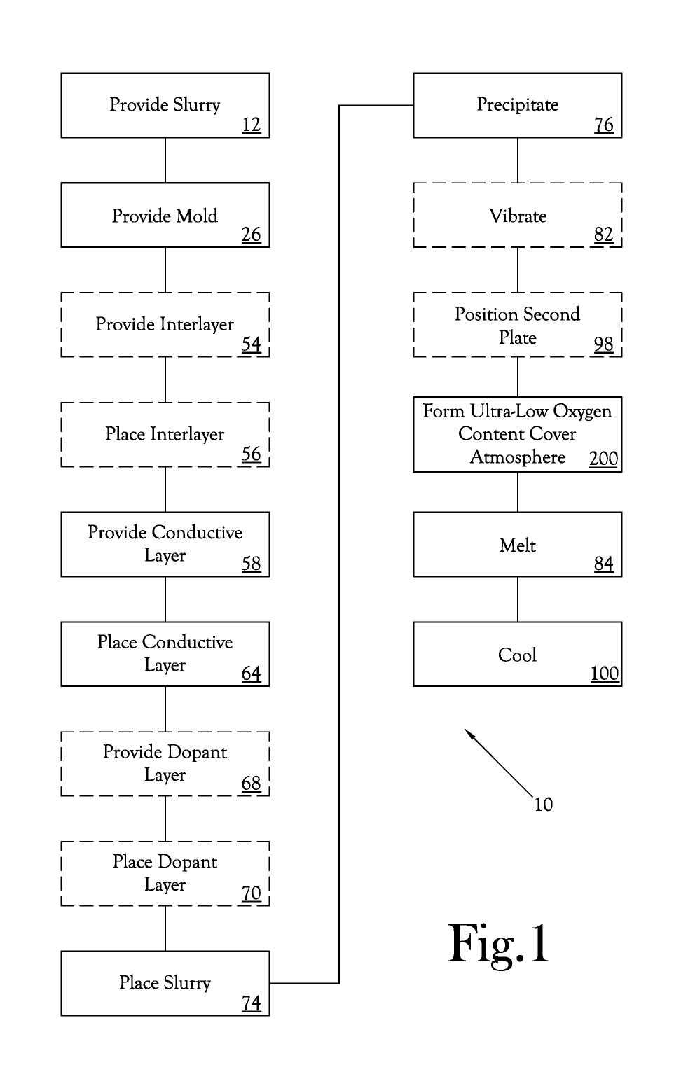

FIG. 1 is a flowchart representing a method 10 of producing a semiconductor. As shown in FIG. 1, the method 10 includes an operation of providing an amount of slurry 12 which is comprised of a silicon powder that is essentially free of oxides and other undesirable impurities and a liquid cover that limits, and preferably essentially prevents, the oxidation of the silicon powder. In at least some embodiments of the present invention, the silicon powder component of the slurry consists essentially of silicon particles having an average size of less than, or equal to, approximately two (2), but preferably less than 1 micron.

The liquid cover component of the slurry prevents or nearly prevents the oxidation of the silicon powder. The slurry is composed of silicon particles whose average particle size is less than one micron. The liquid cover component of the slurry may consist of essentially pure water or essentially water-free ethanol. One object of the present invention is to provide a low cost net shape mold providing a capillary trap and surfaces that will not react with the melted silicon, while lasting for a very long time in daily cycling.

When melting silicon powder to form a silicon wafer in the mold, a higher temperature is required to melt the silicon powder than to sinter the silicon powder. Sintering occurs when the external surface of the silicon particles adheres to the surfaces of other silicon particles. Sintering silicon powder encourages the oxidation-reduction reaction that yields both silicon carbide and the dissolved-oxygen complexes, including silicon-oxygen complexes. Thus, the absence or near absence of silicon oxides (e.g., silica (SiO₂)) and other undesirable impurities in or on the silicon powder prior to melting, promotes the melting of the small silicon particles into a liquid pool, rather than the sintering of the small silicon particles. Small silicon particles with an oxidized exterior surface will form a liquid inside of an oxide skin, but will not flow into a liquidus pool. Even at elevated temperatures in excess of 1500 C, the oxidized exteriors of such particles will show no evidence of the oxidized exteriors having melted.

The liquid cover, when combined with the silicon powder to form the slurry before milling, and being removed prior to melting, protects the silicon from absorbing other gasses, including nitrogen and oxygen. In the case of a finely divided silicon powder, the liquid cover limits contamination of the exterior surfaces of the silicon powder prior to melting.

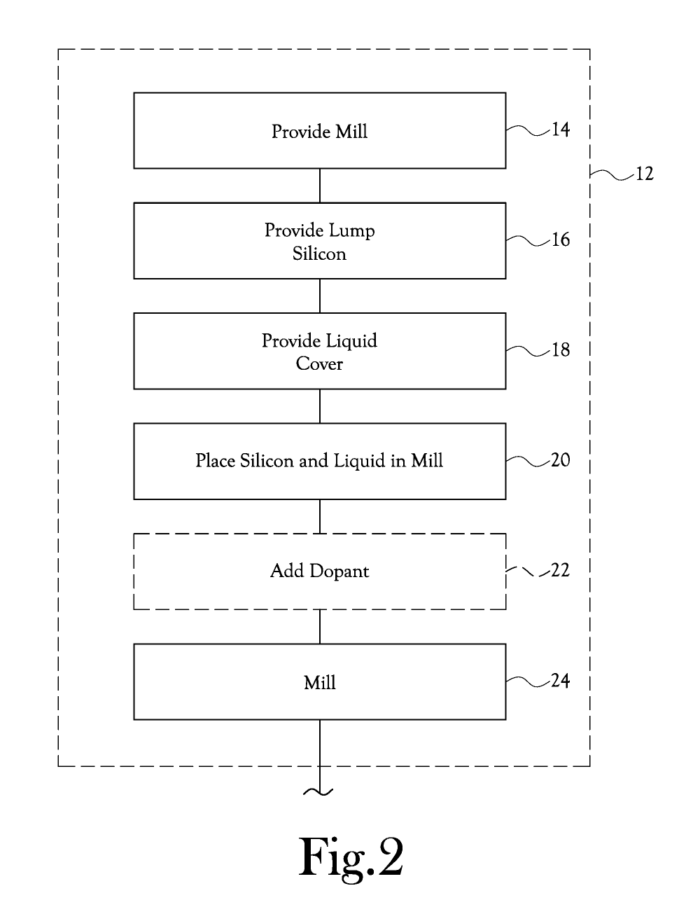

In one embodiment, the operation 12 of providing the slurry includes a series of operations associated with producing the slurry to be used in the method 10. FIG. 2 is a flowchart illustrating one embodiment of a method of producing the slurry 12. In an initial operation, a mill is provided 14 having internal milling and containment surfaces fabricated from a non-reactive material, such as for example silicon nitride, such that a material may be contained and milled within the mill with limited, and preferably no, contact to surfaces other than silicon nitride surfaces within the mill. For example, in certain embodiments, an attrition mill is provided 14 having paddles defining fully dense, oxygen free, pure silicon nitride outer surfaces, linings along the internal portions of the mill, and media. The silicon nitride outer surfaces, linings, and media may be formed through chemical vapor deposition (CVD) or physical vapor deposition (PVD) of fully dense, oxygen free, pure silicon nitride on the interior surfaces of the mill, as well as other known methods. Other types of grinding and milling apparatus defining other configurations of milling and containment surfaces may be used.

A measure of essentially pure lump silicon is provided in 16. In one embodiment, the lump silicon provided in 16 consists of bulk pieces of silicon, each bulk silicon piece being greater than approximately 99.999% pure (hereinafter referred to as “five-nines purity”). In another embodiment, each bulk silicon piece is approximately 99.9999999% pure (hereinafter referred to as “nine-nines purity”). In another operation, the liquid cover 18 is provided. The essentially pure lump silicon and liquid cover are combined and introduced into the mill to form a slurry. In the illustrated embodiment, combination of the lump silicon with the liquid cover and introduction of the combination thereof into the mill occurs simultaneously as both the lump silicon and the liquid cover are placed 20 into the attrition mill. However, it will be understood that, depending upon the specific type of mill provided 14 and the procedure for loading items to be milled therein, the chemically reactive nature of the lump silicon and the need to protect the lump silicon from reacting with atmospheric contaminants may require combination of the lump silicon with the liquid cover at a time other than the time at which the lump silicon and liquid cover are loaded into the mill. To this effect, in another embodiment, the lump silicon and liquid cover are combined and then the combination thereof is introduced into the mill. In yet another embodiment, the lump silicon and liquid cover are first introduced into the mill separately, and then combined within the mill.

Following the combination of the lump silicon with the liquid cover and placing thereof into the mill 20, the mill is activated 24, whereupon the contents of the mill are milled to reduce the average particle size of the lump silicon under the cover of the liquid cover. The silicon nitride milling surfaces and silicon nitride containment surfaces of the mill discourage grinding-based or attrition-based contamination of the silicon during milling 24. Also, in an embodiment in which an attrition mill is provided, the attrition milling 24 of the lump silicon encourages diminution of the silicon into powder wherein the average grain size of the silicon is reduced to a very fine particle size, i.e., less than 150 microns in one embodiment, and less than 300 nanometers in another embodiment. Silicon particles of this approximate size have a similar lattice structure and are substantially non-conductive. In a preferred embodiment, the liquid cover consists of a cryogen, such as for example liquid nitrogen, liquid argon, or other such suitable cryogen, such that the milling 24 of the lump silicon within the liquid cover occurs as cryogenic milling. Such cryogenic milling of the lump silicon results in speedier and more efficient diminution of the lump silicon into powder, and furthermore results in easier reduction of the silicon average grain size to a very fine particle size. However, it will be understood that such cryogenic milling of the lump silicon is not necessary to accomplish the method 10 of the present invention.

In an optional operation, prior to or during milling 24 of the lump silicon, at least one dopant is added 22 to the mixture of silicon and liquid cover. As will be described in further detail below, the method 10 ultimately results in the silicon powder and dopant mixture being separated from the liquid cover and melted to form a doped silicon wafer. Thus, upon melting the silicon powder including the dispersed dopant, the resultant wafer exhibits a uniformly dispersed mixture of the dopant and silicon. In one embodiment, the dopant is phosphorous, thereby resulting in an n-type junction in the resultant silicon wafer. In another embodiment, the dopant is boron, thereby resulting in a p-type junction in the silicon wafer. In embodiments in which the at least one dopant is added 22, such dopant may be added to the lump silicon, to the liquid cover, or to the combination thereof at any time prior to the conclusion of milling 24, such that the process of milling 24 the lump silicon and liquid cover results in substantially uniform dispersion of the dopant into the slurry. Those skilled in the art will recognize other methods for producing a slurry of a silicon powder that is essentially free of oxides and other undesirable impurities and a liquid cover, and such methods may be used without departing from the spirit and scope of the present invention.

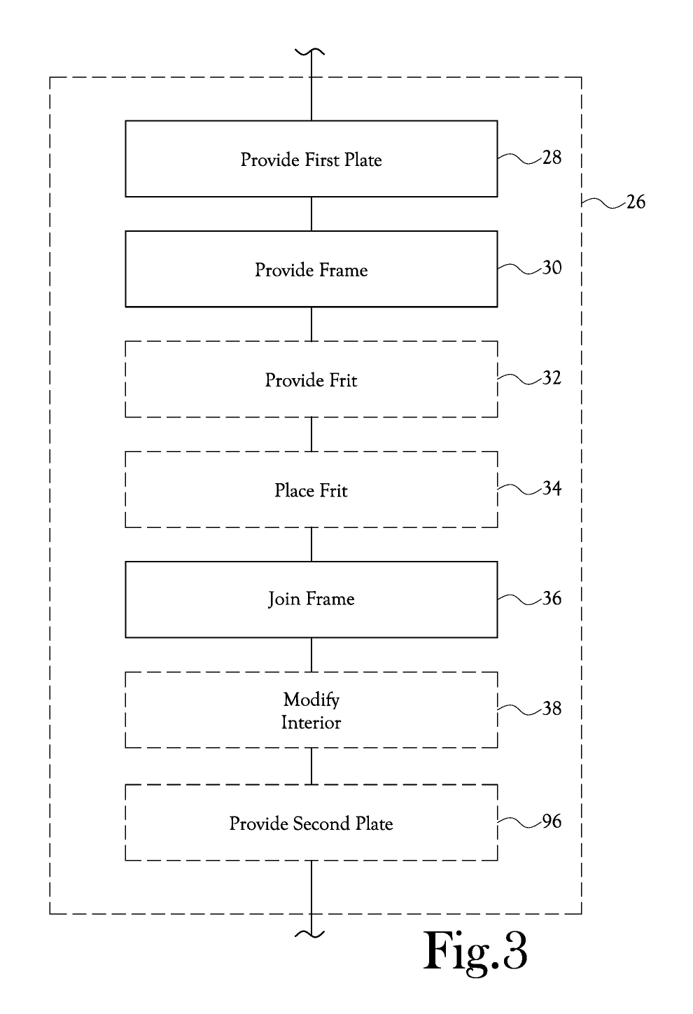

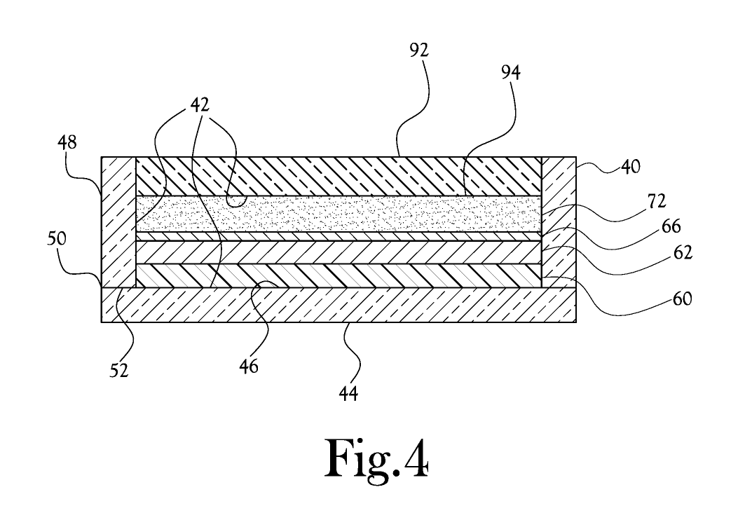

Referring again to FIG. 1, once the slurry is provided 12, a solar grade wafer mold (“mold”) is provided 26. FIG. 3 illustrates a method of providing the mold 26 used in one embodiment of the method 10 of the present invention, and FIG. 4 illustrates a cross-sectional view of the mold 40. As shown in FIG. 4, the mold 40 defines a set of interior surfaces 42 conforming generally to the shape of the desired finished silicon wafer. The mold 40 is selected from a material that allows heating and melting of silicon powder placed within the mold 40, and as will further be discussed below, the composition of the mold 40 is, at least in part, dependent upon the device to be used in heating and melting the silicon powder 42. In other embodiments in which electricity is used to heat the silicon powder, the mold is selected to be electrically resistive of such electricity, such that electricity passing through the mold is converted to heat, thereby causing heating of the mold. Those skilled in the art will recognize other materials suitable for composition of the mold 40.

It is known that minimization of the grain boundaries between sides of a thin silicon wafer used in a solar cell is desirable to allow greater efficiency of conversion of photons to electrons. Thus, in an optional operation shown in the illustrated embodiment, the interior surface 42 of the mold is modified 38 to improve the process of melting silicon to form a silicon wafer while maintaining the purity and crystal alignment of the melted and crystallized silicon. For example, in one embodiment, the interior surface 42 of the mold is modified 38 to yield a mold interior surface 42 that (1) essentially does not react with silicon and (2) has a crystal structure similar to that of silicon. In certain embodiments, modification 38 of the mold interior surface includes deposition of a layer of material along the interior surface 42 of the mold. For example, in one embodiment, such modification is accomplished by applying a layer of non-reactive, substantially non-porous material, such as for example fully dense, oxygen free silicon nitride or pyrolytic graphite, to the interior surface 42 of the mold using a method selected from the group consisting of sputtering, chemical vapor deposition (CVD), physical vapor deposition (PVD), ion implantation, and metalizing. It will be understood that, in one embodiment, one purpose of the interior cavity modification 38 is to aid in orienting silicon crystals within the mold 40 as melted silicon crystallizes within the mold 40. For example, in one embodiment, the modification 38 allows the mold 40 to be differentially cooled from the bottom of the solar grade wafer mold, thereby orienting the crystals to grow from the bottom interior surface 46 of the mold 40 upward.

Modification 38 may be a silicon nitride coating applied to the mold interior surface 42. Silicon nitride powder (Si₃N₄), a water-soluble organic dispersing agent and a binder are combined in pure water with stirring to form a coating composition that is then sprayed onto the mold interior surface 42. Preferably, the water-soluble organic dispersing agent and the binder are pre-combined in the water and then added to the silicon nitride powder. The resulting slurry forming the coating composition may then be sprayed onto one or more interior surface 42 of the mold 40. Preferably, the mold is heated to between 50-70 C before spraying. The slurry also may be heated to between 50-70 C before spraying. The mold 40 may then be allowed to dry at the 50-70 C temperature for approximately 3 hours and allowed to cool before use.

The silicon nitride powder, such as the Japanese UBE silicon nitride powder available from H.C. Starck (Germany), is finely divided and is more than 98% pure. A preferable quantity of the silicon nitride powder is 450 grams; however, other amounts may be chosen depending on the size of the mold 40. The water-soluble organic dispersing agent may be polyacrylic acid (PAA) or ethanolamine in 1-5% (weight dispersing agent/weight of the silicon nitride powder). The binder may be polyvinyl alcohol (PVA), hydroxypropyl methyl cellulose (HPMC), or latex in 0.5-5% (weight dispersing agent/weight of the silicon nitride powder). Milling in the attrition mill is essential to making a submicron slurry. Pure water in the amount of 1,000 to 1,300 mL may be used, depending on the quantity of the silicon nitride powder.

The modification 38 reduces contamination of the resulting silica ingot by the mold. As the formed silica ingot is desired to have a purity of 99.9999%, and the quarts or graphite mold 40 has a purity of approximately 99.7%, contaminants from the mold 40, which may include carbon, oxygen, boron, and phosphorous, may be transferred to the silica ingot during formation.

As discussed above, an amount of dopant, such as arsenic, phosphorous, boron, or other dopant, may be optionally mixed directly into the fine-milled silicon to assist in creating a p-type or n-type junction in the silicon in situ during melting. Following provision 26 of the mold 40 and application into the mold 40 of the interlayer 56, the conductive layer 64, and the dopant layer 66 as described above, the slurry 72 is introduced 74 into the mold 40. Thereafter, the slurry 72 is distributed into an even layer within the mold 40. In certain embodiments (not shown), at least a portion of the interior surface of the mold is treated with a separating agent to facilitate even distribution of the slurry 72 and to discourage beading of the slurry 72 within the mold 40. In certain more discreet embodiments, only the portion of the mold 40 that is to be in contact with the slurry 72 is treated with the separating agent.

In selecting the separating agent, it is desirable to select a separating agent that does not react with the slurry or the mold. Accordingly, in one embodiment, the separating agent is selected to be substantially non-porous. In another embodiment, the separating agent is selected to be a material not containing an oxide or other substance reactive with the slurry or the mold. In another embodiment, the separating agent is selected to be a material that does not include transition metals, organometallics, or the like. In certain embodiments that include treatment of at least a portion of the mold with a separating agent, the separating agent is silicon nitride. In other embodiments, the separating agent is silicon carbide and/or silicon nitride. Those skilled in the art will recognize other suitable separating agents which may be used without departing from the spirit and scope of the present invention. The treatment encourages the slurry to spread across a bottom interior surface of the mold, thus encouraging the formation of a solar grade silicon wafer having a uniform thickness spreading throughout the entire mold. A main function of the separating agent is to allow the capillary design of the tooling to trap the thin wafer without reacting with the capillary trapping surfaces.

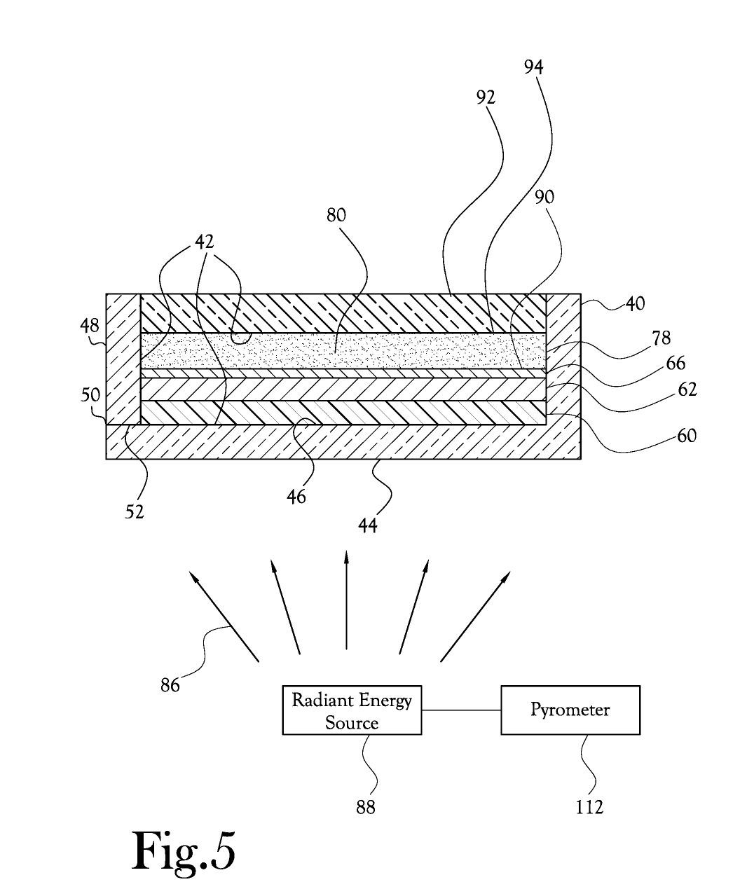

Referring to FIGS. 1 and 5, the silicon powder 78 is precipitated 76 from the slurry 72 to form a preform 80 of a solar grade silicon wafer within the mold 40 opposite the interlayer 60 from the bottom interior surface 46 of the mold 40. Such precipitation 76 of the silicon powder 78 from the slurry 72 may occur by evaporation of the liquid component of the slurry 72. As shown in the optional operation of FIG. 1, the mold 40 may be vibrated 82 to encourage the deposition of a uniform layer of the silicon powder 78 within the mold 40. In addition to or in an alternative to evaporation, freeze casting can be used to accomplish precipitation 76 of the silicon powder 78 from the slurry 72, thus further limiting oxidation of the silicon powder 78. Other methods and techniques may be used accomplish precipitation 76 of the silicon powder 78 from the slurry 72 to form the preform 80.

When the silicon powder 78 component of the slurry 72 consists essentially of silicon particles having an average size of less than, or equal to, approximately two (2) mm, the preform 80 resulting from precipitation 76 may have a packing density of approximately 75%. In relation to the conventional approximately 35% packing density provided by larger lumps of silicon, the approximately 75% packing density provides lower permeability of the silicon by undesirable contaminants and higher thermal conductivity between individual silicon particles in the preform 80. This lower permeability reduces the percentage of the preform's internal surface area that is accessible to carbon oxide gases, thereby reducing the number of loci available for the reactions that produce silicon carbide and silicon oxides within the silicon powder 78. The higher thermal conductivity permits a reduction in the length of the heating cycle, further limiting the synthesis of impurities.

As shown in FIGS. 4 and 5, in several embodiments, the mold 40 includes a second plate 92 which is optionally provided 96 (see FIG. 3) and positioned 98 adjacent the silicon powder 78 opposite the first plate 44 of the mold 40. The second plate 92 is spaced apart from the first plate 44 a distance sufficient to establish a planar capillary space 94 between the first and second plates 44, 92. In one embodiment, in which the first plate 44 lies substantially horizontally below the silicon 78, dopant 66, conductive layer 62, and interlayer 60, the second plate 92 is disposed horizontally, resting on the substantially horizontal layer of silicon powder 78. In another embodiment, the second plate 92 is secured to and supported by the remainder of the mold 40. Those skilled in the art will recognize other suitable means for positioning the second plate 92 in overlapping, spaced apart relation to the first plate 44 so as to establish the planar capillary space 94, and such other means may be used without departing from the spirit and scope of the present invention. Small geometries can be built into either or both plates that may leverage the capillary forces in play to cause a net shape planer object to be formed which will have particular geometries useful for photovoltaic cells as well as other applications including anodes for lithium ion secondary batteries. For instance micron scaled ridges or furrows or rows can be used on one surface for light trapping. The same can be used to create surface area and isolation between anode and cathode structures in a lithium ion secondary battery.

Following precipitation 76 of the silicon powder 78 from the slurry 72 and optional vibration 82 and placement of the second plate 92, the preform 80 of the solar grade silicon wafer is melted 84 and cooled 100 to form a solar grade silicon wafer adjacent the conductive layer 62, thereby forming a solar cell. Heating the preform 80 to the point of melting 84 generally increases the reactivity of the silicon forming the preform 80. Thus, in several embodiments, melting of the preform 80 is performed through a high energy heating device during a brief time interval. For example, in several embodiments, melting 84 of the preform 80 is performed during a time interval of less than five minutes and at a temperature of less than 1450 degrees Centigrade. In one embodiment, melting 84 of the preform occurs during a time interval of less than one minute and at a temperature of approximately 1435 degrees Centigrade.

Referring to FIG. 5, in one embodiment, the mold 40 containing the silicon preform 80, the interlayer 60, the conductive layer 62, and the dopant layer 66, as described above, is placed in an ultra-low oxygen content cover atmosphere (not shown) which further discourages oxidation of the silicon preform 80. Upon melting 84 of the silicon preform 80, an amount of silicon vapor is released into the cover atmosphere surrounding the mold 40.

An ultra-low oxygen content cover atmosphere includes less than 1×10¹⁹ oxygen atoms in 63.8 liters of the cover atmosphere. An ultra-low oxygen content cover atmosphere preferably includes less than 1×10¹⁷ oxygen atoms in 63.8 liters of the cover atmosphere, and more preferably less than 1×10¹⁵ oxygen atoms in 63.8 liters of the cover atmosphere. In an especially preferred at present ultra-low oxygen content cover atmosphere, approximately 1×10¹⁴ oxygen atoms or less are present in 63.8 liters of the cover atmosphere.

Purging the oven containing the mold 40 with an inert gas, such as argon, before heating will reduce the oxygen atoms in 63.8 liters of the cover atmosphere to about 1×10²⁰, as turbulence considerations and other factors prevent the oxygen content from going lower in the cover atmosphere with purging. The 1×10²⁰ oxygen atoms per 63.8 liters of the cover atmosphere is too much oxygen in the cover atmosphere to prevent the formation of silica oxide contaminants at the temperature at which the silicon is melted to produce the semiconductor for the solar cell.

The ultra-low oxygen content cover atmosphere reduces formation of a silica oxide or other oxide “skin” that otherwise would preclude melting or flowing of the small particles of silicon at the approximately 1414 C melt temperature of silicon. Even if heated to a point where the silicon within the skin may be molten, the silicon will not flow to form a substantially homogeneous liquid. Thus, the ultra-low oxygen content cover atmosphere allows for melting of the small particles of silicon at lower temperatures than in conventional systems using argon purging. The lower melt temperature allows formation of a semiconductor have significantly reduced contaminants in relation to conventional processes.

In 200 of FIG. 1, the ultra-low oxygen content cover atmosphere is formed surrounding the mold 40. While other methods may be used to form the ultra-low oxygen content cover atmosphere, a preferred method includes a conventional argon purge as the mold 40 is heated to about 300 C. A vacuum of 0.2 to 2 microns (10⁻⁵ to 10⁻⁶ Torr) is then applied to form the ultra-low cover atmosphere surrounding the mold 40. Argon purge may be maintained during vacuum application so a reduced pressure of approximately 1×10⁻⁵ to one atmosphere is achieved for the cover atmosphere surrounding the mold 40 until the mold 40 reaches about 700 C. The purge also may be ended when the vacuum is applied and the vacuum maintained until the final melt temperature is reached. In another preferred method of forming the ultra-low atmosphere surrounding the mold 41, the vacuum is applied first as the mold 40 is heated. When the mold 40 reaches approximately 300 C, the argon is introduced to increase the pressure of the cover atmosphere surrounding the mold 40 to approximately 1×10⁻⁵ to one atmosphere until the mold reaches approximately 700 C. The argon is then turned off and the vacuum allowed to reach the limit as the mold 40 is heated to the final melt temperature.

In addition to the significantly reduced oxygen content of the ultra-low oxygen content cover atmosphere in relation to a conventional cover atmosphere, the forming of the ultra-low oxygen content cover atmosphere and the avoidance of the use of the fused silica crucible also reduces the iron and alkaline earth metal contamination of the resulting semiconductor. While not wishing to be bound by any particular theory, the substantial reduction in iron and alkaline earth metal contamination is believed to arise from these materials being volatilized during heating and mixing with the flow of argon gas that is removed by the vacuum pump as well as from the migration of grain boundary zone refining in the fused silica crucible.

Upon exposure to the radiant energy 86 of the radiant energy source 88, the silicon powder 78 absorbs the radiant energy 86 and very rapidly melts at temperatures in excess of 1420 degrees Centigrade. However, once the outer layer of the silicon powder 78 melts into liquid silicon, the resulting very pure liquid silicon is more transparent to the radiant energy 86 from the radiant energy source 88. Thus, once melted, a greater portion of the radiant energy 86 passes through the melted portion of the silicon preform 80 to adjacent particles of silicon powder 78. In this manner, the radiant energy source 88 heats and melts the silicon preform 80 while leaving the glass mold 40 substantially unmelted.

As discussed above, upon melting the silicon preform 80, the radiant energy source is deactivated, thereby discontinuing exposure of the mold 40 and the silicon 78, dopant 66, conductive layer 62, and interlayer 60 contained therein to the radiant energy 86 from the radiant energy source 88. As part of the operation 84 of melting the silicon preform 80, the temperature of at least one of the mold 40 and the silicon preform 80 may be monitored to verify that the radiant energy source 88 has heated the silicon preform 80 to a temperature sufficient to melt the silicon preform. For example, at least one pyrometer 112 is provided to monitor the temperature of at least one of the mold 40 and the silicon preform 80 and to provide a signal indicating the monitored temperature. In one embodiment, the pyrometer 112 is placed in communication with the radiant energy source 88 such that, once the silicon preform 80 has melted, the pyrometer 112 generates and communicates a signal to the radiant energy source 88 to deactivate the radiant energy source 88.

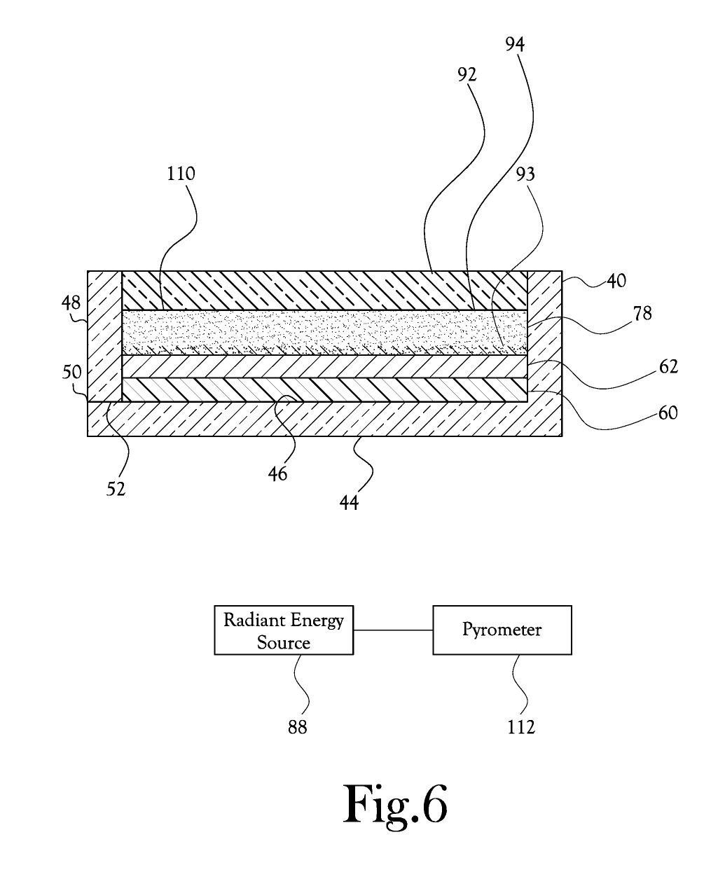

Referring to FIGS. 5 and 6, in embodiments in which the dopant layer 66 is provided 68 and placed 70 in the mold 40, at an interface 90 of the melted silicon 78 with the dopant layer 66, the dopant 66 diffuses and reacts with the silicon 78, resulting in a boundary 93 between the conductive layer 62 and the melted silicon 78 which is rich in substances helpful in forming a P-N junction. For example, in the illustrated embodiment, in which the provided dopant 66 is boron, the boundary 93 between the conductive layer 62 and the melted silicon 78 is rich in silicon hexaboride, a very desirable element in the P-N junction of the resultant solar cell for increasing solar cell efficiency.

In embodiments in which the second plate 92 is provided to form the planar capillary space 94, upon melting the silicon 78, the melted silicon 78 wicks throughout the capillary space 94 to substantially fill the capillary space 94 adjacent the second plate 92. Thereafter, the melted silicon 78 and other contents of the mold 40 are allowed to cool 100 and to form columnar growth crystalline structures within the silicon 78, thereby forming a solar grade silicon wafer 110 adjacent the conductive layer 62, and thereby forming a solar cell.

In embodiments in which the interlayer 60 is provided, the interlayer 60 provides a bond to the mold 40 and a mechanical stress reliever to the stress that builds up due to the expansion and contraction of the silicon 78 during heating 84 and cooling 100, while the mold 40 remains relatively cool. In embodiments in which the second plate 92 is positioned to form the capillary space 94 in the mold 40, the capillary wicking of the melted silicon 78 allows the wafer preform 80 to be melted quickly and thinly, often but not necessarily with a thickness of the melted and cooled silicon in the range of 400 microns or less, and in certain embodiments, less than 200 microns.

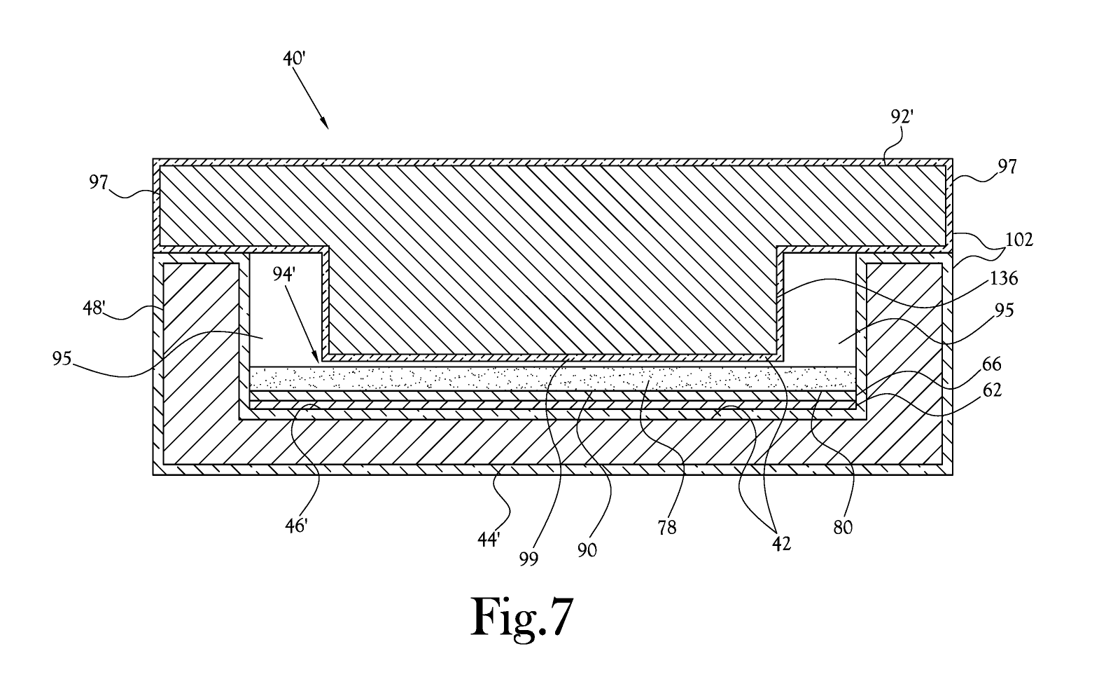

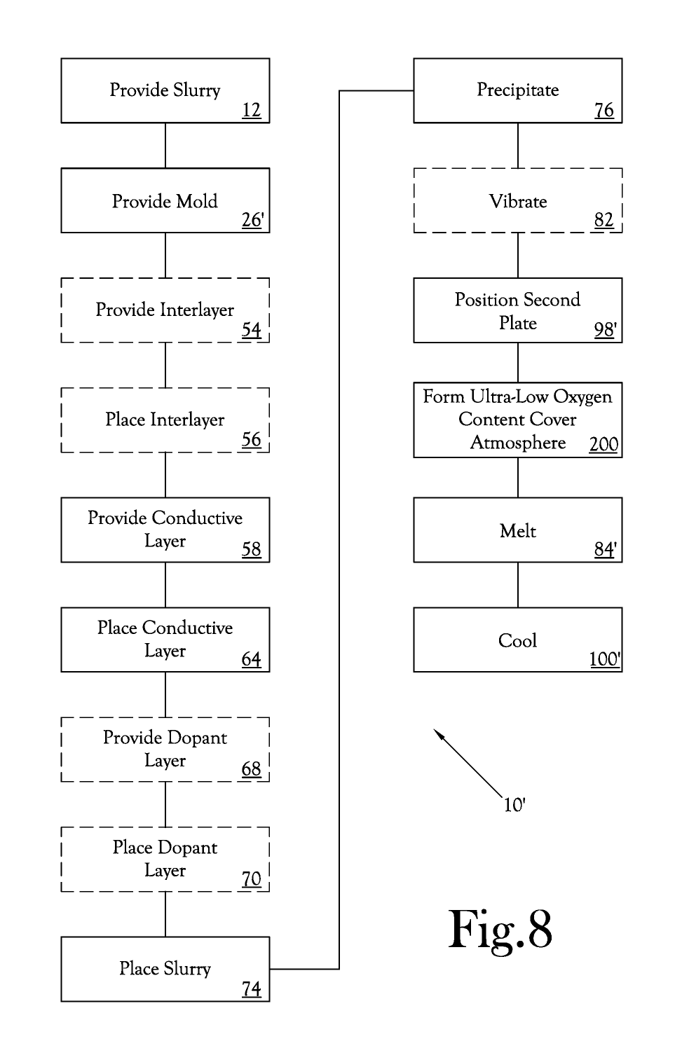

The material for fabricating the mold may be selected to accommodate various features of the particular heating apparatus used. Accordingly, FIG. 7 illustrates a cross-sectional view of another mold 40′, which may be used in another embodiment of the method 10′, illustrated in FIG. 8. The method 10′ employs an induction heating apparatus 104 for melting 84′ and cooling 100′ the silicon preform 80. Accordingly, in the illustrated embodiment of FIGS. 7 and 8, a mold 40′ is provided 26′, which is composed of a material easily warmed through inductive heating, such as for example graphite, pyrolytic graphite, or the like. As discussed above, the mold 40′ defines a set of interior surfaces 42′ conforming generally to the shape of the desired finished solar cell. Similarly to the embodiment discussed above, the mold 40′ includes a bottom first plate 44′ which defines an upper surface 46′ conforming to an interior bottom surface of the desired mold 40′. A circumferential lip 48′ is integrally formed along the perimeter of the upper surface 46′ of the plate 44′ and extends generally upwardly from the plate 44′, such that the lip 48′ cooperates with the plate 44′ to define a vessel to prevent loss of the silicon powder from the interior 42′ of the mold 40′. At least the interior surfaces 42′ of the mold 40′, and preferably all surfaces of the mold 40′, are coated with a ceramic material 102, which is substantially non-reactive to liquid silicon and silicon powder. In several embodiments, the ceramic material 102 is selected from the group consisting of silicon nitride, silicon carbide, and fused quartz. In one embodiment, the ceramic material 102 is selected to be silicon nitride formed by spraying, painting, or otherwise applying a coating composition slurry onto the interior surfaces of the mold 40′, as previously discussed.

A second plate 92′ is provided in a parallel, spaced apart relationship to the first plate 44′ to establish a capillary space 94′ between the first and second plates 44′, 92′. In the illustrated embodiment, the second plate 92′ can include a rectangular first portion 136 having a lower surface 99 configured to be positioned in a parallel-planar, offset relationship to the upper surface 46′ of the first plate 44′ to define the capillary space 94′. A circumferential flange 97 extends horizontally from an upper portion of the first portion 136 and is sized to rest along the circumferential lip 48′ to position the first portion lower surface 99 within the mold 40′ to define the capillary space 94′. In the illustrated embodiment, the first portion 136 of the second plate 92 is sized slightly smaller than the space defined within the circumferential lip 48′. In this embodiment, the first portion 136 can be received generally centered within and offset from the circumferential lip 48′, such that a relief space 95 is defined between the lip 48′ and the first portion 136.

Similarly to the mold 40′, the second plate 92′ can be coated with a ceramic material 102, which is substantially non-reactive to silicon powder as discussed above. In certain embodiments of the method 10′, the operation of providing 26′ the mold 40′ includes a series of operations for coating the mold 40′ with the ceramic material 102.

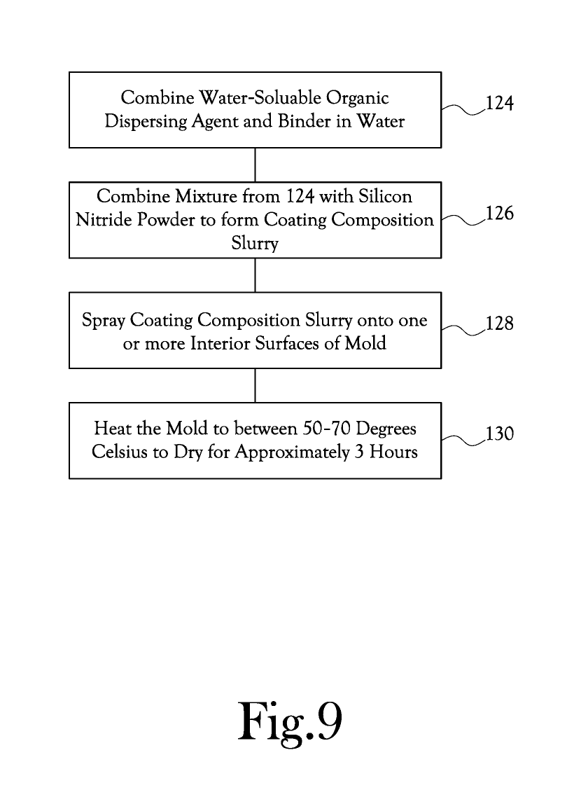

FIG. 9 represents a method of coating one or more interior surfaces of the mold 40′ with silicon nitride. In 124, a water-soluble organic dispersing agent and binder are combined in water. In 126, this mixture is combined with silicon nitride powder to form a coating composition slurry. In 128, the coating composition slurry is sprayed onto one or more interior surfaces of the mold 40′. In 130, the mold is heated from 50 to 70 C to dry for approximately 3 hours.

Referring to FIGS. 7 and 8, in the illustrated embodiment of the method 10′, the slurry is provided 12 as discussed above. Following the above-discussed provision 26′ of the mold 40′, an interlayer 60 is optionally provided 54 and placed 56 in the mold 40′ to create a forgiving layer to allow thermal expansion and contraction of solar cell materials along the interior of the mold 40′ and a delaminating layer to assist in removal of at least one of the second plate 92′ and the mold 40′ from the finished solar cell. The conductive layer 62 is provided 58 and placed 64 in the mold 40′ opposite the interlayer 60 from the mold 40′. The dopant layer 66 is optionally provided 68 and placed 70 in the mold 40′ along the conductive layer 62 opposite the first plate 44′ of the mold 40′. The slurry is then placed 74 into the mold 40′, precipitated 76, and optionally vibrated 82 as discussed above to create the silicon preform 80, whereupon the second plate 92′ is positioned 98′ proximate the first plate 44′ to form the capillary space 94′ between the second plate 92′ and the mold 40′.

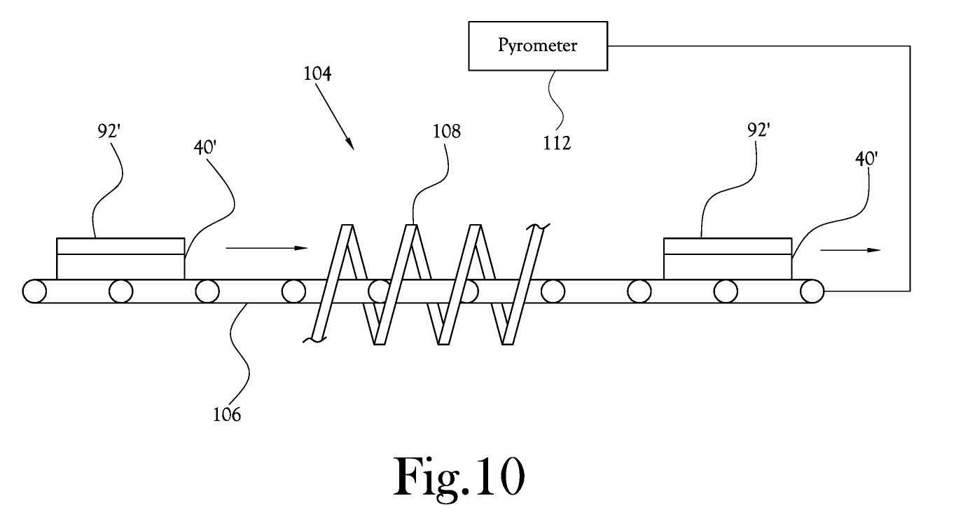

Referring to FIGS. 8 and 10, following precipitation 76 of the silicon powder 78 from the slurry, optional vibration 82, and placement of the second plate 92′, the preform 80 of the solar grade silicon wafer is melted 84′ using an inductive heater 104 to form a solar grade silicon wafer adjacent the conductive layer 62, thereby forming a solar cell. The mold 40′ containing the various unfinished components of the solar cell, including the silicon preform 80, is placed within a cover atmosphere (not shown) which discourages oxidation of the silicon preform 80. As previously discussed in the context of radiant heating, for inductive heating an ultra-low oxygen content cover atmosphere also is used during the melting process. Heating in a vacuum furnace may be achieved by induction, radiation, resistance convection, or other heating method.

As shown in FIG. 10, while within the cover atmosphere, which may or may not be an ultra-low oxygen content cover atmosphere at this juncture, the mold 40′ is conveyed by a conveyor, pushed along rails, or otherwise conveyed by a similar conveyance device 106 through a series of inductive coils 108 of the type known to one of ordinary skill in the art. As the mold 40 passes through the inductive coils 108, the inductive coils 108 couple with the material forming the mold 40′ to rapidly heat the mold 40′, thereby also rapidly heating and melting the silicon preform 80. The ultra-low oxygen content cover atmosphere is formed during the heating process as previously described.

In one embodiment, the inductive coils 108 consist of a set of water-cooled inductive coils, which are sized and shaped to conform closely to the shape of the combined mold 40′ and plate 92′, such that inductive coupling between the material forming the mold 40′ and plate 92′ and the inductive coils 108 is maximized. However, numerous configurations for the inductive coils 108 suitable for use in the method 10′ will be recognized by one of skill in the art.

As discussed above, in certain embodiments, a pyrometer 112 is provided to monitor the temperature of the silicon preform 80 and to verify melting of the silicon preform 80. Following melting 84′ of the silicon preform 80 within the mold 40′, the mold 40′ and its contents are allowed to cool 100′. In the illustrated embodiment, such cooling 100′ of the mold 40′ is accomplished by further conveying the mold 40′ and its contents out from within the inductive coils 108, whereupon heating 84′ of the mold 40′ ceases, and the mold 40′ and its contents are allowed to cool 100′. In one embodiment a pyrometer 112 is provided in communication with the conveyor to signal the conveyor to convey the mold 40′ and its contents out from within the inductive coils 108 upon melting of the silicon preform 80.

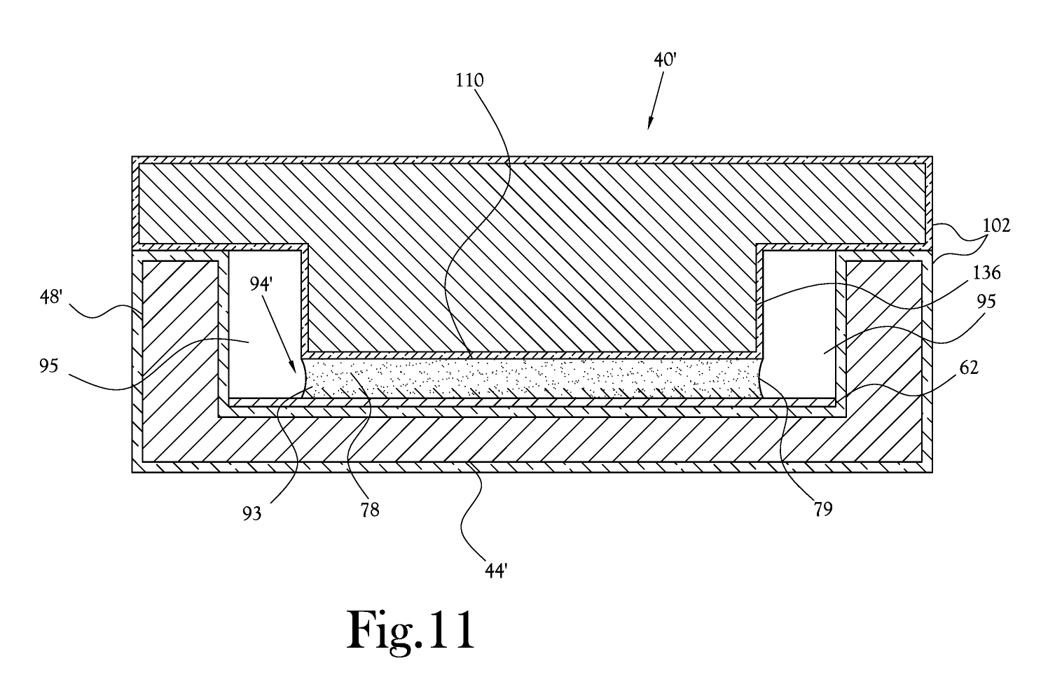

Referring to FIG. 11, upon melting of the silicon 78 within the mold 40′, the melted silicon 78 wicks within the capillary space 94′ to substantially fill the capillary space 94′. In the illustrated embodiment, the melted silicon 78 forms a meniscus 79 at an interface between the capillary space 94′ and the relief space 95. Thereafter, the melted silicon 78 and other contents of the mold 40 are allowed to cool 100′, whereupon the relief space 95 serves to allow any necessary thermal expansion of the silicon 78 from within the capillary space 94′. Cooling 100′ of the melted silicon preform allows the melted silicon 78 to form columnar growth crystalline structures, thereby forming a solar grade silicon wafer 110 adjacent the conductive layer 62, and thereby forming a solar cell. As discussed above, in embodiments in which the dopant layer 66 is provided 68 and placed 70 in the mold 40′, at an interface 90 of the melted silicon 78 with the dopant layer 66, the dopant 66 diffuses and reacts with the silicon 78, resulting in a boundary 93 between the conductive layer 62 and the melted silicon 78 which is rich in substances helpful in forming a P-N junction.

Melting of the preform 80 may be performed during a brief time interval, such as for example less than five minutes, so as to avoid excessive oxidation and other such contamination of the silicon forming the preform 80. However, the speed at which the silicon preform 80 is melted and cooled through heating and cooling of the mold 40′ is, at least in part, dependent upon the size of the mold 40′, and silicon preform 80 disposed within, to be heated and cooled. More specifically, the greater the mass of mold materials and silicon to be heated and cooled, the longer the time period required for exposure of the mold 40′ and silicon preform 80 to a constant-state heat source in order to accomplish melting of the silicon preform 80, and the longer the time period required following removal of the mold 40′ and silicon preform 80 from the heat source until the silicon cools. However, a smaller mold 40′ generally exhibits a smaller overall interior cavity, and thus results in a smaller resultant solar cell. Thus, the general dimensions of the mold 40′ may vary in order to generally maximize the size of the resultant solar cell while minimizing the energy necessary to accomplish melting 84′ and cooling 100′ of the mold 40′ and silicon preform 80. For example, the mold 40′ may include a generally square first plate 44′, beveled circumferential lip 48′, and second plate 92′, each having a square geometry and defining a thickness of between approximately 5-25 millimeters. In this embodiment the interior surface 46′ of the first plate 44′ defines a dimension of approximately 156 millimeters square, and the capillary space 94′ defined by the interior 42 of the mold 40′ is approximately 160 microns thick. In this embodiment, the above-discussed inductive coils 108 are capable of heating and melting the mold 40′ to a temperature of approximately 1435 degrees Centigrade in approximately 10 seconds. In a more discreet embodiment, each of the first plate 44′, beveled circumferential lip 48′, and second plate 92′, defines a thickness of approximately 10 millimeters.

In order to utilize the finished solar cell produced through the method invention 10, the solar cell must be capable of being exposed to ambient light energy. Accordingly, when a mold 40 and second plate 92 are used that are substantially transparent to ambient light energy, the finished solar cell may remain within the mold 40 for end use. To this extent, in certain embodiments in which an interlayer 60 is used, the interlayer 60 provides a bond between the mold 40 and the finished solar cell. In such embodiments, the mold 40 provides additional structural support to the finished solar cell to discourage fracture and wear of the finished solar cell. However, when the mold 40′ and second plate 92′ are substantially opaque to ambient light energy, such represented in FIGS. 7-10, at least the second plate 92′ is removed from the finished solar cell to expose the solar grade silicon wafer of the solar cell to ambient light energy. Accordingly, at least one delaminating layer may be provided within the combined mold 40′ and second plate 92′ prior to melting 84′ of the silicon preform 80 to assist in removal of at least one of the second plate 92′ and the mold 40′ from the finished solar cell. For example, when the interlayer 60 is optionally provided 54, the interlayer 60 may serve to enable delamination of at least one of the second plate 92′ and the mold 40′ from the finished solar cell. When the various components of the mold 40′ are coated with a ceramic material 102, the ceramic material 102 may serve to enable delamination of at least one of the second plate 92′ and the mold 40′ from the finished solar cell. However, additional delaminating layers may be provided.

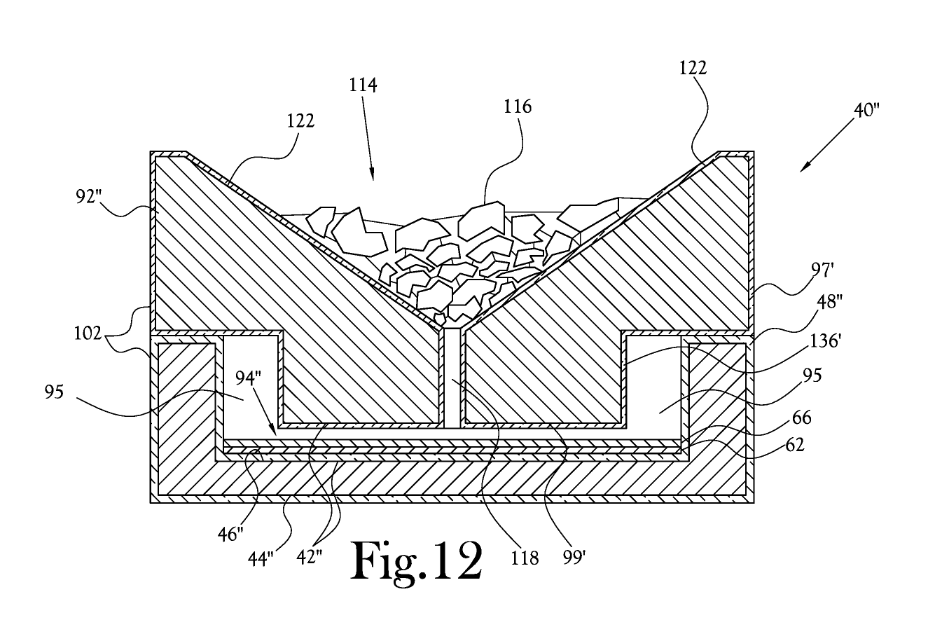

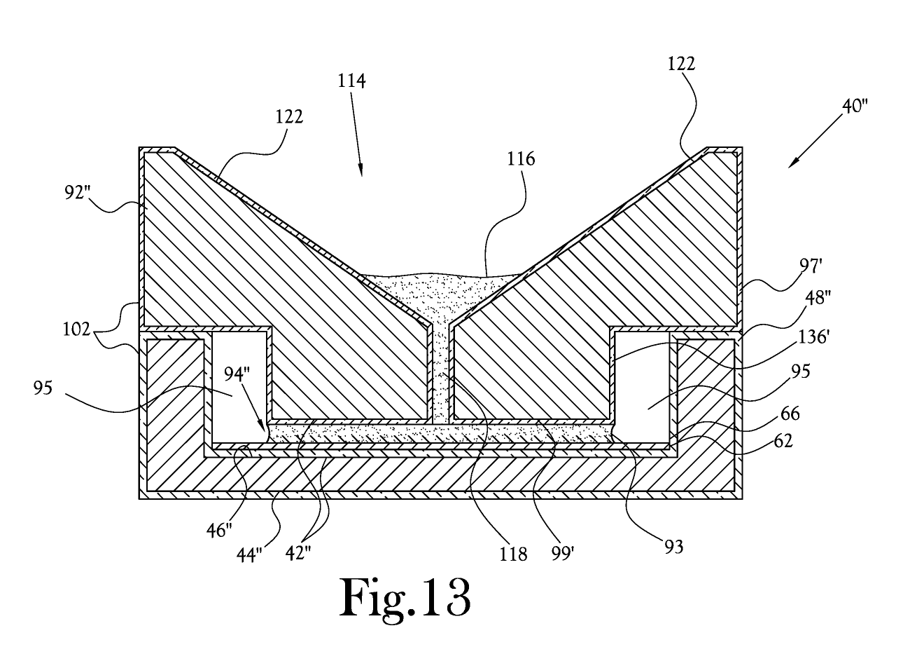

FIGS. 12 and 13 illustrate a cross-sectional view of another mold 40″, which is used in another embodiment of the method of the present invention. In this embodiment, the mold 40″ defines generally a vessel 114 for holding a measure of silicon 116 and an inlet 118 for introducing melted silicon 78 into the capillary space 94″ defined by the mold 40″. Thus, in this embodiment, the operation of placing silicon within the capillary space 94″ occurs simultaneously, or near simultaneously, to the operation of melting the silicon.

Similarly to the previous embodiment of the mold 40′ discussed above, the mold 40″, such as shown in FIGS. 12 and 13, defines a set of interior surfaces 42″ conforming generally to the shape of the desired finished solar cell and including a bottom plate 44″, which defines an upper surface 46″ conforming to an interior bottom surface of the desired mold 40″. A circumferential lip 48″ is integrally formed along the perimeter of the upper surface 46″ of the plate 44″ and extends generally upwardly and outwardly from the plate 44″, such that the lip 48″ cooperates with the plate 44″ to prevent loss of the various raw components of the finished solar cell from the interior 42″ of the mold 40″. A cap 92″ is provided in a parallel, spaced apart relationship to the plate 44″ to establish a capillary space 94″ between the plate 44″ and the cap 92″. In the illustrated embodiment, the cap 92″ includes a rectangular first portion 136′ having a lower surface 99′ configured to be positioned in a parallel-planar, offset relationship to the upper surface 46″ of the plate 44″ to define the capillary space 94″. A circumferential flange 97′ extends horizontally from an upper portion of the first portion 136′ and is sized to rest along the circumferential lip 48″ to position the first portion lower surface 99′ within the mold 40″ to define the capillary space 94″. In the illustrated embodiment, the first portion 136′ of the cap 92 is sized slightly smaller than the space defined within the circumferential lip 48″ such that a relief space 95′ is defined between the lip 48″ and the first portion 136′ as discussed above. At least the interior surfaces 42″ of the mold 40″, and preferably all surfaces of the mold 40″, including the cap 92″, are coated with a ceramic material 102, which is substantially non-reactive to silicon powder as discussed above.

In the illustrated embodiment, the cap 92″ defines a vessel 114 for holding a measure of essentially pure silicon 116. More specifically, the cap 92″ defines a plurality of upwardly and outwardly sloping beveled walls 122 along an upper surface thereof to define the vessel 114 there between. A central portion of the cap 92″ defines an inlet 118 in the form of a through opening providing fluid communication between the vessel 114 and the capillary space 94″ defined between the first plate 44″ and the cap 92″ of the mold 40″. The inlet 118 may be sized to allow the flow of melted silicon from the vessel 114 into the capillary space 94″. The inlet 118 may be sized to allow the flow of melted silicon from the vessel 114 into the capillary space 94″, while limiting the entry of unmelted silicon into the capillary space 94″.

As discussed above, following provision of the mold 40″ as discussed above, an interlayer 60 is optionally provided and placed in the mold 40″ to create a forgiving layer to allow thermal expansion and contraction of solar cell materials along the interior of the mold 40″ and a delaminating layer to assist in removal of at least one of the cap 92″ and the mold 40″ from the finished solar cell. The conductive layer 62 is provided and placed in the mold 40″ opposite the interlayer 60 from the mold 40″. The dopant layer 66 is optionally provided and placed in the mold 40″ along the conductive layer 62 opposite the first plate 44″ of the mold 40″. In separate operations, a measure of silicon 116 is placed in the vessel 114 defined by the cap 92″, and the cap 92″ is placed over the interior 42″ of the mold 40″ to define the capillary space 94″.

Assembly of the various raw components of the semiconductor may take place within a cover atmosphere as discussed above. Thereafter, the silicon 116 within the vessel 114 is melted within the ultra-low oxygen content cover atmosphere. Upon melting of the silicon 116 within the vessel 114, melted silicon 78 is allowed to flow through the inlet 118 and into the capillary space 94″, whereupon the melted silicon 78 wicks throughout the capillary space 94″ to substantially fill the capillary space 94″ adjacent the cap 92″. In the illustrated embodiment, the melted silicon 78 forms a meniscus 79 at an interface of the capillary space 94″ with the relief space 95, such that the relief space 95 allows for thermal expansion of the silicon 78 upon cooling 100 as discussed above. Thereafter, the melted silicon 78 and other contents of the mold 40 are allowed to cool 100 and to form columnar growth crystalline structures within the silicon 78, thereby forming a solar grade silicon wafer 110 adjacent the conductive layer 62, and thereby forming a solar cell. As discussed above, at an interface 90 of the melted silicon 78 with the dopant layer 66, the dopant 66 diffuses and reacts with the silicon 78, resulting in a boundary 93 between the conductive layer 62 and the melted silicon 78 which is rich in substances helpful in forming a P-N junction.

It will be understood that the above-discussed cooling of the melted silicon 78 to form the solar grade silicon wafer 110 results in slight thermal expansion of the silicon within the mold 40. To accommodate such thermal expansion upon cooling 100, in the illustrated embodiment discussed above, the mold 40′ defines suitable relief spaces 95 adjacent and in fluid connection with the capillary space 94′ to permit such thermal expansion and contraction. In another embodiment, the melted silicon 78 is permitted to wick only partially into the capillary space 94′ prior to cooling 100, such that sufficient unfilled space remains within the capillary space 94 to accommodate thermal expansion of the silicon upon cooling 100. In yet another embodiment, the mold 40 and defined capillary space 94 is of a geometry such that the meniscus 79 formed by the melted silicon 78 provides sufficient space within the mold 40 to allow the melted silicon 78 to expand upon cooling 100.

The above-discussed operations of reducing essentially pure lump silicon into silicon powder in the presence of a liquid cover can result in unintentional exposure of the silicon to impurities, thereby reducing the overall efficiency of the resultant solar cell as discussed above. Thus, in certain embodiments using the cap 92″ including the vessel 114 and inlet 118 as shown in FIGS. 12 and 13, melted silicon 78 is introduced into the capillary space 94″ of the mold 40″ absent the operation of providing silicon powder in a slurry 12. To this extent, in one embodiment, the silicon 116 provided in the vessel 114 is granular silicon. In another embodiment, the silicon 116 provided in the vessel 114 is lump silicon. In yet another embodiment, the silicon 116 provided in the vessel 114 is a single, unitary piece of essentially pure silicon. However, regardless of the initial grain size of the silicon 116 provided, use of the cap 92″ including the vessel 114 and inlet 118 as shown in FIGS. 11 and 12, allows melted silicon 78 to be introduced into the capillary space 94″ of the mold 40″ to substantially fill and conform to the capillary space 94″.

From the foregoing description, it will be recognized by those skilled in the art that an efficient and cost-effective method of producing a solar cell is provided. The method of producing a solar cell allows for the production of a solar cell with reduced waste of silicon feedstock as compared with certain prior art methods. Use of the radiant energy source, or alternatively the inductive heater, as described hereinabove in the method of producing a solar cell allows for melting and crystallization of the silicon powder to form the solar grade silicon wafer more quickly than certain prior art methods described hereinabove. Furthermore, the method of producing a solar cell allows for the production of an efficient solar cell having a desirable boundary between the conductive layer and the melted silicon which improves efficiency of the resultant solar cell.

Some advantages offered by the above-discussed method include: (1) reduced energy consumption to coat one or more interior surfaces of the mold with silicon nitride; (2) reduced contamination of the formed semiconductor with oxygen and other contaminants, thus resulting in less contamination by SiO, SiC, SiO₂, and related species; (3) higher semiconductor yield from approximately 95% (weight/weight) and greater due to less contamination; (4) higher energy output on a mass basis in relation to conventional semiconductors, with semiconductor wafers of from 4 grams to 8 grams having an energy yield of 20% up to approximately 25% and enhanced efficiency due to the processing ability to make net shape thin wafers typically as thin as 20-50 microns, as well as thicker wafers as currently used in the range of 160-800 microns; and (5) larger wafers due to relatively unrestricted processing with regard to size, thus enabling much higher aerial yield on such limited real estate such as roof tops, car tops, etc. For instance, current technology is limited to producing a solar wafer having a length of approximately 15 centimeters and a width of approximately 15 centimeters (approximately 225 cm²). The present invention enables manufacture of a solar wafer having a length of approximately one meter and a width of approximately one meter (approximately 1.0 m²), thereby reducing or eliminating the wafer-to-wafer space losses in a finished solar cell. The vast majority of infrastructure for production of solar cells is based on a wafer that is 156 mm square and about 160 mm thick.

While the present invention has been illustrated by description of several embodiments and while the illustrative embodiments have been described in considerable detail, it is not the intention of the applicant to restrict or in any way limit the scope of the appended claims to such detail. Additional advantages and modifications will readily appear to those skilled in the art. The invention in its broader aspects is therefore not limited to the specific details, representative apparatus and methods, and illustrative examples shown and described. Accordingly, departures may be made from such details without departing from the spirit or scope of applicant's general inventive concept.

What is claimed is:

1. A method of manufacturing a semiconductor having sub millimeter net shape geometries, said method comprising:
introducing a separating layer into a mold having an interior defining the sub millimeter shape geometries;
forming a planar capillary space along at least two planer separating layers;
placing silicon in fluid communication with the capillary space;
melting the silicon in an ultra-low oxygen content cover atmosphere;
flowing the melted silicon into the planar capillary space;
cooling the melted silicon within the planar capillary space; and
forming the semiconductor, the silicon forming one part of a P-N junction, the silicon being doped with either a P-type dopant or a N-type dopant.

2. The method of claim 1, where the melting the silicon is limited to heating the silicon to a temperature less than 1450 degrees Centigrade.

3. The method of claim 1, where the melting the silicon is performed in less than five hours at temperature.

4. The method of claim 1, where the silicon is greater than 99.999% pure.

5. The method of claim 5, where the silicon is at least 99.9999999% pure.

6. The method of claim 1, further comprising:
placing a layer of dopant in the mold between the conductive layer and the capillary space, said dopant being reactive with the melted silicon to produce a compound beneficial in forming the P-N junction of the semiconductor.

7. The method of claim 6, where the dopant is selected from the group consisting of boron, arsenic, and phosphorous.

8. The method of claim 1, where the melting the silicon, the flowing the melted silicon into the capillary space, and the cooling the melted silicon occur under the ultra-low oxygen content cover atmosphere.

9. The method of claim 8, where the ultra-low oxygen content cover atmosphere includes argon gas and less than 1×10¹⁹ oxygen atoms in 63.8 liters of the ultra-low oxygen content cover atmosphere.

10. The method of claim 1, where the mold is fabricated from a material configured to be quickly heated.

11. The method of claim 10, where the mold is fabricated from at least one of quartz, graphite, silicon nitride, and other non-reactive refractory materials.

12. The method of claim 11, where the mold is coated with a material that is substantially non-reactive to melted silicon.

13. The method of claim 12, where the non-reactive material is silicon nitride.

14. The method of claim 13 further comprising:
combining a water-soluble organic dispersing agent and binder in water to form a mixture;
combining the mixture with finely divided silicon nitride to form a coating composition slurry;
applying the coating composition slurry onto one or more interior surfaces of the mold; and
heating the coating to a temperature from 50 to 70 degrees Centigrade to dry the coating composition slurry prior to sintering at 1450 degrees Centigrade in a nitrogen atmosphere.

15. The method of claim 8, the melting the silicon including heating the mold to transfer heat from the mold to the silicon.

16. The method of claim 1 further comprising:
introducing an interlayer between the mold and the conductive layer to facilitate thermal expansion and contraction of the conductive layer along the interior of the mold.

17. The method of claim 1, where the melting the silicon is limited to heating the silicon to a temperature from 1414 to 1450 degrees Centigrade.

18. The method of claim 1, where the melting the silicon is limited to heating the silicon to a temperature from 1420 to 1430 degrees Centigrade.

19. The method of claim 1, where the melting the silicon is limited to heating the silicon to a temperature from 1414 to 1420 degrees Centigrade.
